(19) United States
(12) Patent Application Publication
(10) Pub. No.: US 2007/0152333 A1
(43) Pub. Date: Jul. 5, 2007

(54) Metal Interconnection of Semiconductor Device and Method of Fabricating the Same

(76) Inventor: Han Choon Lee, Seoul (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/616,044

(22) Filed: Dec. 26, 2006

(30) Foreign Application Priority Data
Dec. 29, 2005 (KR) 10-2005-0134363

(51) Int. Cl. H01L 23/52; H01L 21/4763

(52) U.S. Cl. 257/751; 438/627; 257/774; 438/629; 257/E23.145

(57) ABSTRACT

Disclosed are a metal interconnection of a semiconductor device and a method of fabricating the same. The metal interconnection includes an interlayer dielectric layer formed having a trench on a semiconductor layer, a first TaN layer formed at an inner wall of the trench, a second TaN layer formed on the first TaN layer, and a conductive material filling the trench, wherein TaN of the first TaN layer has a grain size smaller than a grain size of TaN of the second TaN layer.

### RELATED APPLICATION(S)

This application claims priority under 35 U.S.C.§119(e) of Korean Patent Application No. 10-2005-0134363 filed Dec. 29, 2005, which is incorporated herein by reference in its entirety.

### FIELD OF THE INVENTION

The present invention relates to a method of fabricating a metal interconnection of a semiconductor device. In addition, the present invention relates to a semiconductor device including a metal interconnection.

### BACKGROUND OF THE INVENTION

As semiconductor devices have become highly-integrated and are operated at a high speed, metal interconnections formed in the semiconductor device are getting micro-sized and multi-layered. As the width of the interconnection becomes reduced, a signal delay may occur due to the resistance and capacitance of the metal interconnection. Thus, in order to reduce the signal delay, copper, which is a low-resistance metal, is used as a material for the metal interconnection.

Copper is rarely etched as compared with other metals such as aluminum. Thus, in order to make a copper interconnection, a damascene process is performed. According to the damascene process, a trench is first formed, and then a copper layer is formed to fill the trench. In this state, chemical mechanical polishing is performed relative to the copper layer, thereby forming the metal interconnection.

However, the copper easily diffuses into other layers, so a diffusion barrier is formed in the trench before the copper is filled in the trench.

The diffusion barrier can be formed using tantalum (Ta). However, the Ta layer does not perfectly prevent the diffusion of copper. Thus, a TaN diffusion barrier has been suggested. However, although the TaN layer can effectively prevent the diffusion of copper, it has a poor adhesion property relative to copper.

For this reason, recently, the diffusion barrier has a dual-layered structure of TaN/Ta to improve reliability of the semiconductor device. Such a diffusion barrier having the dual-layered structure can be formed through PVD (physical vapor deposition), ALD (atomic layer deposition), or CVD (chemical vapor deposition).

The ALD provides superior step coverage as compared with the PVD and CVD.

However, since the ALD forms a thin film through a substitution reaction of gas, the initial incubation time may increase, so the deposition speed is lowered. In addition, since the grain size of the TaN layer is irregular, it is difficult to obtain a uniform thin film.

### BRIEF SUMMARY

Accordingly, an object of embodiments of the present invention is to obtain a uniform thin film while increasing the deposition speed of a TaN layer.

To accomplish the above object, the present invention provides a metal interconnection of a semiconductor device, the metal interconnection comprising: an interlayer dielectric layer formed on a semiconductor substrate and including a trench; a first TaN layer formed at an inner wall of the trench; a second TaN layer formed on the first TaN layer; and a metallic material for filling the trench defined by the second TaN layer, wherein TaN of the first TaN layer has a grain size smaller than a grain size of TaN of the second TaN layer.

In a preferred embodiment, the first and second TaN layers are alternately deposited at least once.

The metal interconnection may further include a third Ta layer formed on the second TaN layer, and a fourth Ta layer formed on the third Ta layer.

In an embodiment, the third and fourth TaN layers are alternately deposited at least once.

The TaN of the third TaN layer can be formed to have a grain size smaller than a grain size of TaN of the fourth TaN layer.

In addition, the present invention also provides a method of fabricating a metal interconnection of a semiconductor device, the method comprising the steps of: forming a first layer including boron (B) on a substrate; converting the first layer into a Ta layer by reacting the first layer with TaF; forming a second layer including silicon (Si) on the first layer; converting the second layer into a Ta layer by reacting the second layer with TaF; and converting the first and second layers into TaN layers by reacting the first and second layers with NH₃.

The method may further include the steps of: forming a third layer including boron (B) on the second layer; converting the third layer into a Ta layer by reacting the third layer with TaF; forming a fourth layer including silicon (Si) on the third layer; converting the second layer into a Ta layer by reacting the second layer with TaF; and converting the third and fourth layers into TaN layers by reacting the third and fourth layers with NH₃.

The first to fourth layers can be formed through atom layer deposition (ALD)

The first and third layers can be formed by using B₂H₆ gas.

The second and fourth layers can be formed by using SiH₄ gas.

The steps of forming the first layer, forming the second layer, and converting the first and second layers into the Ta layer can be repeated.

In an embodiment, at least one of the first and second processes is repeated, wherein the first process includes the steps of forming the first layer, forming the second layer, and converting the first and second layers into the Ta layer, and the second process includes the steps of forming the third layer and forming the fourth layer.

### BRIEF DESCRIPTION OF THE DRAWINGS

FIG. 1 is a sectional view illustrating a metal interconnection of a semiconductor device according to an embodiment of the present invention.

FIGS. 2, 3, 5 and 6 are sectional views illustrating a method of forming a metal interconnection of a semiconductor device according to an embodiment of the present invention.

FIG. 4 is a flowchart showing the procedure for fabricating a metal interconnection of a semiconductor device according to an embodiment of the present invention.

FIG. 7 is a sectional view illustrating a metal interconnection of a semiconductor device according to another embodiment of the present invention.

FIGS. 8 to 11 are sectional views illustrating a method of forming a metal interconnection of a semiconductor device according to another embodiment of the present invention.

FIGS. 12 and 13 are views illustrating a metal interconnection according to another embodiment of the present invention.

### DETAILED DESCRIPTION OF THE INVENTION

Hereinafter, a metal interconnection of a semiconductor device and a method for fabricating the same according to the preferred embodiments of the present invention will be described with reference to the accompanying drawings.

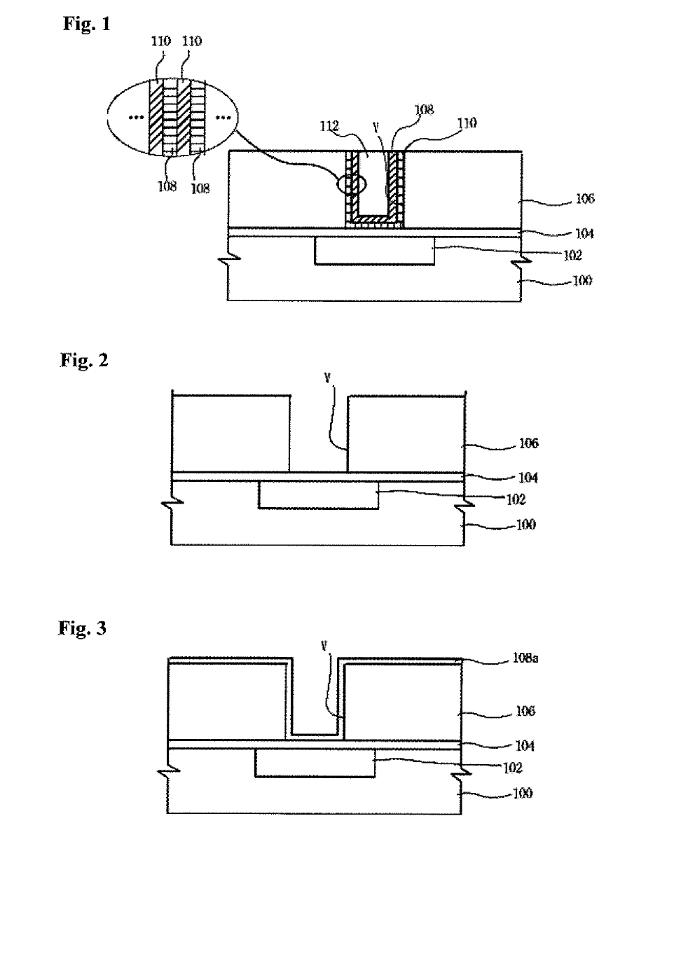

FIG. 1 is a sectional view illustrating a metal interconnection of a semiconductor device according to an embodiment of the present invention.

As shown in FIG. 1, an etch stop layer 104 and an interlayer dielectric layer 106 can be stacked on a substrate 100. The substrate 100 may include individual elements (not shown) and a lower conductor 102.

The lower conductor 102 may be formed of, for example, copper (Cu), aluminum (Al), tungsten (W), silver (Ag), gold (Au), or platinum (Pt). The etch stop layer 104 may be formed of SiN or SiH₄. The interlayer dielectric layer 106 can be prepared in the form of a single layer or a multi-layer by depositing inorganic insulating materials or organic insulating materials, such as FSG (fluorine silicate glass), USG (un-doped silicate glass), SiH4, or TEOS (tetra ethyl ortho silicate). In addition, the interlayer dielectric layer 106 can be formed with a material having a low dielectric constant, such as BD (black diamond) having a dielectric constant of 3.0 or less.

A trench T and/or a via V can be formed in the etch stop layer 104 and the interlayer dielectric layer 106 so as to expose the lower conductor 102.

Barrier layers 108 and 110 and a metal interconnection 112 can be formed in the via V (and/or trench T) so as to be electrically connected with the lower conductor 102. The barrier layers 108 and 110 can be formed along inner walls of the via V and/or a trench T. The metal interconnection 112 can be a metal layer which is filled in the trench defined by the barrier layers 108 and 110.

The barrier layers 108 and 110 prevent metallic materials from diffusing into other layers, such as insulating layers, and enhance the adhesion property between the insulating layer and the metal interconnection 112. The barrier layers 108 and 110 can include a first TaN layer 108 and a second TaN layer 110. The first and second TaN layers 108 and 110 can be alternately formed at least once. In a preferred embodiment, the first and second TaN layers 108 and 110 can be formed alternating at least twice. The metal layer can include conductive materials, such as copper which is a low-resistance metal.

Hereinafter, a method of forming the metal interconnection of the semiconductor device having the above structure will be described with reference to FIGS. 2 to 6.

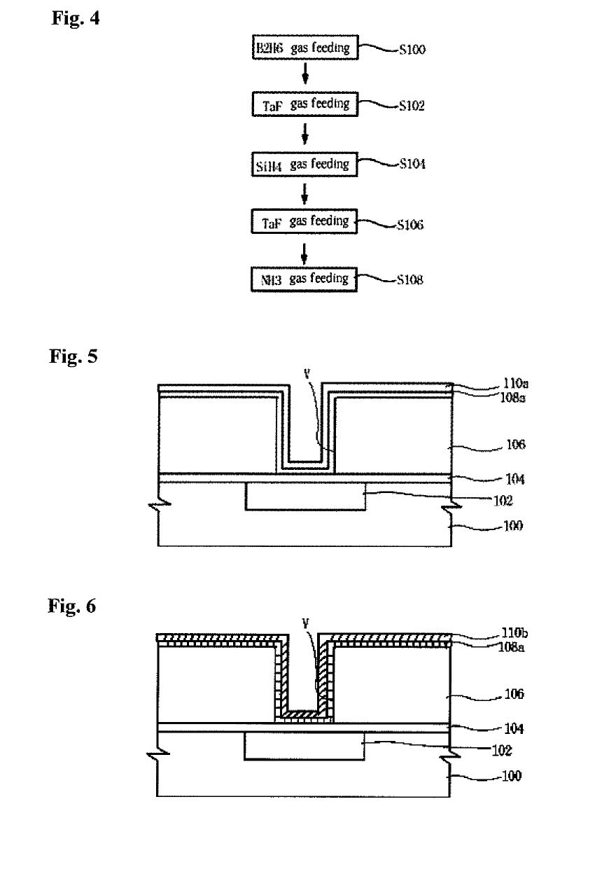

FIGS. 2, 3, 5 and 6 are sectional views sequentially illustrating a method of forming the metal interconnection of the semiconductor device from a middle step according to an embodiment of the present invention, and FIG. 4 is a flowchart showing the procedure for fabricating the metal interconnection of the semiconductor device according to an embodiment of the present invention.

Referring to FIG. 2, an etch stop layer 104 and an interlayer dielectric layer 106 can be stacked on a substrate 100 including a lower conductor 102.

Then a via V (or trench T) exposing the etch stop layer 104 can be formed in the interlayer dielectric layer 106 by selectively etching the interlayer dielectric layer 106 using a photoresist film (not shown) as a mask.

Then, referring to FIGS. 3 and 4, the exposed etch stop layer 104 can be removed to expose the lower conductor 102. Then, a first Ta layer 108a can be formed through an ALD process.

In a preferred embodiment, the first Ta layer 108 can be formed as follows:

First, in a state in which the substrate 100 is maintained at a temperature in the range of 100° C. to 500° C., reaction gas such as B₂H₆ is fed into ALD equipment (S100), thereby forming a first layer including boron (B).

Then, TaF gas is fed (S 102) in such a manner that the TaF gas can react with the first layer. Accordingly, boron (B) of the first layer may react with F (fluoride) of the TaF gas, thereby generating BF. At this time, the first layer becomes the first Ta layer 108a. The BF is removed through a purge process.

Then, referring to FIGS. 4 and 5, SiH₄ gas is fed (S104) so as to form a second layer including silicon (Si) on the first Ta layer 108a.

Subsequently, TaF gas is fed (S106) so that the second layer reacts with the TaF gas. Accordingly, Si of the second layer may react with F of the TaF gas, thereby generating SiF. At this time, the second layer becomes the second Ta layer 110a. The SiF is removed through a purge process.

Next, referring to FIGS. 4 and 6, the substrate 100 can be plasma-treated using NH₃ (S108), thereby forming first and second TaN layers 108a and 110b. Nitrogen may react with Ta of the first and second TaN layers 108a and 110b, thereby creating TaN.

At this time, the total thickness of the first and second TaN layers 108a and 110b can be about 0.5 Å to 5 Å.

The procedure (S100 to S108) shown in FIG. 4 can be repeated to form the first and second TaN layers 108a and 110b having a desired thickness. In a preferred embodiment, the total thickness of the first and second TaN layers 108a and 110b is about 10 Å to 300 Å.

Then, referring back to FIG. 1, a copper layer can be formed such that the via (or trench), which is defined by the first and second TaN layers 108b and 110b, can be filled with copper. Then, the substrate can be planarized through a CMP process, thereby forming the metal interconnection including the barrier layers 108 and 110 and the copper layer.

In this manner, if the Ta layer is formed using B₂H₆ and SiH₄, a portion of the barrier layer that makes contact with the insulating layer can be prepared as a highly densified layer having a small grain size by means of B₂H₆. In addition, if the thin film is formed by using SiH₄, the deposition speed for the thin film may increase, so that the productivity is improved.

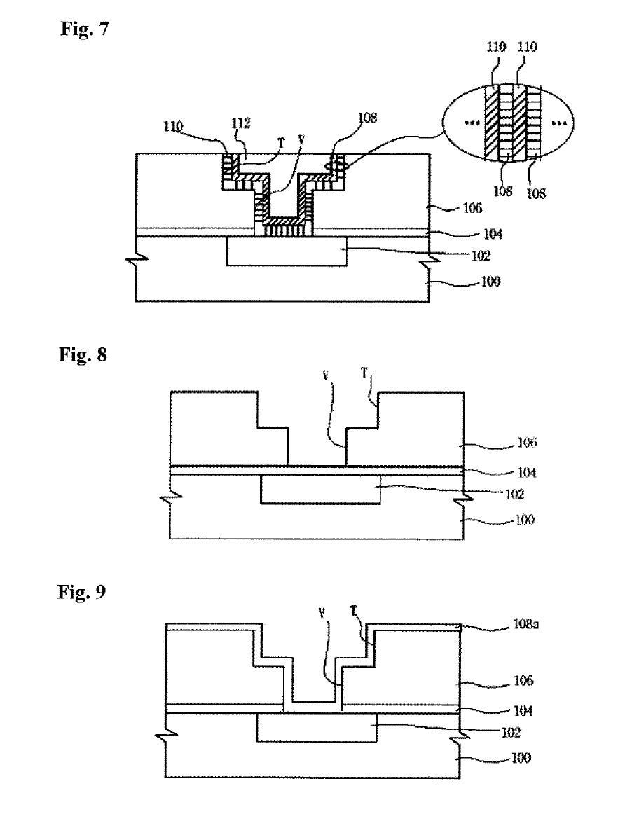

FIG. 7 is a sectional view illustrating a metal interconnection of a semiconductor device according to another embodiment of the present invention.

As shown in FIG. 7, an etch stop layer 104 and an interlayer dielectric layer 106 can be stacked on a substrate 100. The substrate 100 may include individual elements (not shown) and a lower conductor 102.

The lower conductor 102 may be formed of, for example, copper (Cu), aluminum (Al), tungsten (W), silver (Ag), gold (Au), or platinum (Pt). The etch stop layer 104 may be formed of SiN or SiH₄. The interlayer dielectric layer 106 can be prepared in the form of a single layer or a multi-layer by depositing inorganic insulating materials or organic insulating materials, such as FSG (fluorine silicate glass), USG (un-doped silicate glass), SiH4, or TEOS (tetra ethyl ortho silicate). In addition, the interlayer dielectric layer 106 can be formed with a material having a low dielectric constant, such as BD (black diamond) having a dielectric constant of 3.0 or less.

A via V can be formed in the etch stop layer 104 and the interlayer dielectric layer 106 so as to expose the lower conductor 102. In addition, a trench T can be formed in the interlayer dielectric layer 106 so as to expose the via V.

Barrier layers 108 and 110 and a metal interconnection 112 can be formed in the via V and trench T so as to be electrically connected with the lower conductor 102. The barrier layers 108 and 110 can be formed along inner walls of the via V and the trench T. The metal interconnection 112 can be a metal layer which is filled in the trench defined by the barrier layers 108 and 110.

The barrier layers prevent metallic materials from diffusing into other layers, such as insulating layers, and enhance the adhesion property between the insulating layer and the metal interconnection 112. The barrier layers 108 and 110 can include a first TaN layer 108 and a second TaN layer 110. The first and second TaN layers 108 and 110 can be alternately formed at least once. In a preferred embodiment, the first and second TaN layers 108 and 110 can be formed alternating at least twice. The metal layer can include conductive materials, such as copper which is a low-resistance metal.

Hereinafter, a method of forming the metal interconnection of the semiconductor device having the above structure will be described with reference to FIGS. 8 to 11.

FIGS. 8 to 11 are sectional views sequentially illustrating a method of forming the metal interconnection of the semiconductor device from a middle step according to another embodiment of the present invention

Referring to FIG. 8, an etch stop layer 104 and an interlayer dielectric layer 106 can be stacked on a substrate 100 including a lower conductor 102.

In addition, a via V exposing the etch stop layer 104 can be formed in the interlayer dielectric layer 106 by selectively etching the interlayer dielectric layer 106 using a photoresist film (not shown) as a mask. Then, a trench T exposing the via V can be formed by performing a selective etching process using a second photoresist film (not shown) as a mask. If the interlayer dielectric layer 106 is prepared in the form of a multi-layer, one of the interlayer dielectric layers 106 may serve as an etch stop layer for forming the trench T.

Then, referring to FIGS. 9 and 4, the exposed etch stop layer 104 can be removed to expose the lower conductor 102. Then, a first Ta layer 108a can be formed through an ALD process.

The first Ta layer 108 can be formed as follows:

First, in a state in which the substrate 100 is maintained at a temperature in the range of 100° C. to 500° C. reaction gas such as B₂H₆ is fed into ALD equipment (S100), thereby forming a first layer including boron (B).

Then, TaF gas is fed (S 102) in such a manner that TaF gas can react with the first layer. Accordingly, boron (B) of the first layer may react with F of the TaF gas, thereby generating BF. At this time, the first layer becomes the first Ta layer 108a. The BF is removed through a purge process.

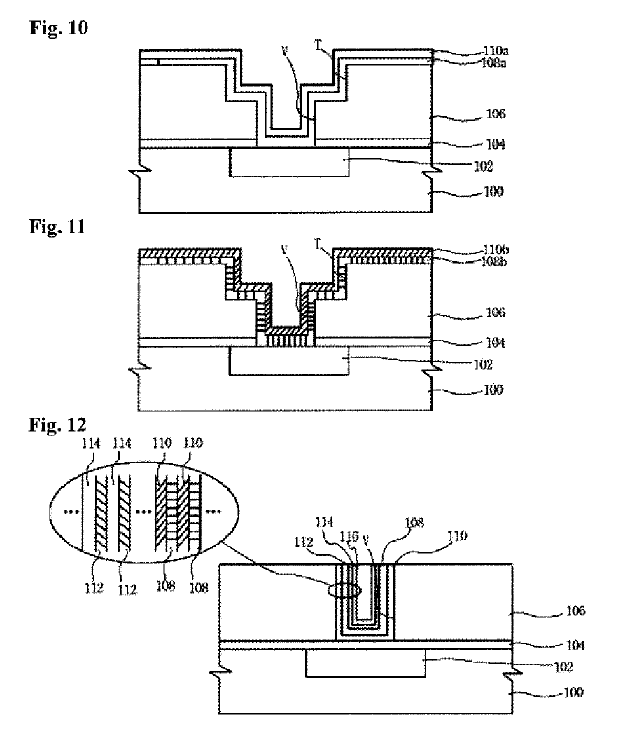

Then, referring to FIGS. 4 and 10, SiH₄ gas is fed (S104) so as to form a second layer including silicon (Si) on the first Ta layer 108a.

Subsequently, TaF gas is fed (S106) so that the second layer reacts with the TaF gas. Accordingly, Si of the second layer may react with F of the TaF gas, thereby generating SiF. At this time, the second layer becomes the second Ta layer 110a. The SiF is removed through a purge process.

Next, referring to FIGS. 4 to 11, the substrate 100 can be plasma-treated using NH₃ (S108), thereby forming first and second TaN layers 108a and 110b. Nitrogen may react with Ta of the first and second TaN layers 108a and 110b, thereby creating TaN.

At this time, the total thickness of the first and second TaN layers 108a and 110b can be about 0.5 Å to 5 Å.

The procedure (S100 to S108) shown in FIG. 4 can be repeated several times to form the first and second TaN layers 108a and 110b having a desired thickness. In a preferred embodiment, the total thickness of the first and second TaN layers 108a and 110b is about 10 Å to 300 Å.

Then, referring back to FIG. 7, a copper layer can be formed such that the trench and the via, which are defined by the first and second TaN layers 108b and 110b, can be filled with copper. Then, the substrate can be planarized through a CMP process, thereby forming the metal interconnection including the barrier layers 108 and 110 and the copper layer.

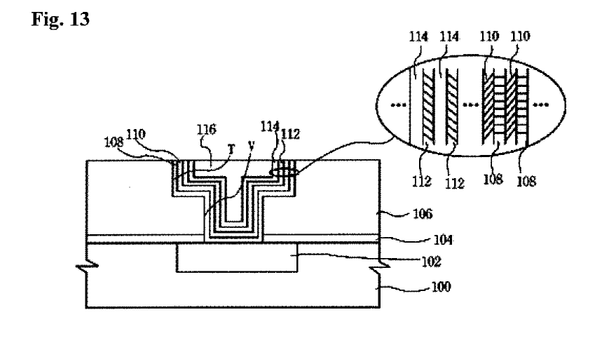

FIGS. 12 and 13 are views illustrating a metal interconnection according to another embodiment of the present invention.

As shown in FIG. 12, an etch stop layer 104 and an interlayer dielectric layer 106 can be stacked on a substrate 100. The substrate 100 may include individual elements (not shown) and a lower conductor 102.

The lower conductor 102 can be formed of, for example, copper (Cu), aluminum (Al), tungsten (W), silver (Ag), gold (Au), or platinum (Pt). The etch stop layer 104 may be formed of SiN or SiH₄. The interlayer dielectric layer 106 can be prepared in the form of a single layer or a multi-layer by depositing inorganic insulating materials or organic insulating materials, such as FSG (fluorine silicate glass), USG (un-doped silicate glass), SiH4, or TEOS (tetra ethyl ortho silicate) In addition, the interlayer dielectric layer 106 can be formed with a material having a low dielectric constant, such as BD (black diamond) having a dielectric constant of 3.0 or less.

A via V (or trench T) can be formed in the etch stop layer 104 and the interlayer dielectric layer 106 so as to expose the lower conductor 102.

Barrier layers 108, 110, 112 and 114, and a metal interconnection 116 can be formed in the trench T so as to be electrically connected with the lower conductor 102. The barrier layers 108, 110, 112 and 114 can be formed along inner walls of the via V (or trench T). The metal interconnection 116 can be a metal layer which is filled in the trench defined by the barrier layers 108, 110, 112 and 114.

The barrier layers 108, 110, 112 and 114 prevent metallic materials from diffusing into other layers, such as insulating layers, and enhance the adhesion property between the insulating layer and the metal interconnection 116. The barrier layers 108, 110, 112 and 114 include a first TaN layer 108, a second TaN layer 110, a third Ta layer 112 and a fourth Ta layer 114. The first and second TaN layers 108 and 110 can be alternately deposited at least once. In addition, the third and fourth Ta layers 112 and 114 can be alternately deposited at least once. The metal layer can include conductive materials, such as copper which is a low-resistance metal.

Referring to FIG. 13, an etch stop layer 104 and an interlayer dielectric layer 106 can be stacked on a substrate 100. The substrate 100 may include individual elements (not shown) and a lower conductor 102.

The lower conductor 102 may be formed of, for example, copper (Cu), aluminum (Al), tungsten (W), silver (Ag), gold (Au), or platinum (Pt). The etch stop layer 104 may be formed of SiN or SiH₄. The interlayer dielectric layer 106 can be prepared in the form of a single layer or a multi-layer by depositing inorganic insulating materials or organic insulating materials, such as FSG (fluorine silicate glass), USG (un-doped silicate glass), SiH4, or TEOS (tetra ethyl ortho silicate). In addition, the interlayer dielectric layer 106 can be formed with a material having a low dielectric constant, such as BD (black diamond) having a dielectric constant of 3.0 or less.

A via V can be formed in the etch stop layer 104 and the interlayer dielectric layer 106 so as to expose the lower conductor 102. In addition, a trench T can be formed in the interlayer dielectric layer 106 so as to expose the via V.

Barrier layers 108, 110, 112 and 114, and a metal interconnection 116 can be formed in the via V and the trench T so as to be electrically connected with the lower conductor 102. The barrier layers 108, 110, 112 and 114 can be formed along inner walls of the via V and the trench T. The metal interconnection 116 can be a metal layer which is filled in the trench and via defined by the barrier layers 108, 110, 112 and 114.

The barrier layers 108, 110, 112 and 114 prevent metallic materials of the metal interconnection 116 from diffusing into other layers, such as insulating layers, and enhance the adhesion property between the insulating layer and the metal interconnection 116. The barrier layers 108, 110, 112 and 114 include a first TaN layer 108, a second TaN layer 110, a third Ta layer 112 and a fourth Ta layer 114. The first and second TaN layers 108 and 110 can be alternately formed at least once. In addition, the third and fourth Ta layers 112 and 114 can be alternately formed at least once. The metal layer can include conductive materials, such as copper, which is a low-resistance metal.

As described above, according to embodiments of the present invention, the diffusion barrier, which is not affected by a step difference, can be formed through an ALD process, so that the reliability of the semiconductor device can be improved. In addition, since the Ta layer is formed by using B₂H₆ and SiH₄, the Ta layer can be rapidly formed by adjusting the deposition speed while varying the reaction gas according to the state of the thin film.

It will be apparent to those skilled in the art that various modifications and variations can be made in the present invention. Thus, it is intended that the present invention covers the modifications and variations thereof within the scope of the appended claims.

I claim:

1. A metal interconnection of a semiconductor device, comprising:
an interlayer dielectric layer formed comprising a contact hole on a semiconductor substrate;
a first TaN layer formed at an inner wall of the contact hole;
a second TaN layer formed on the first TaN layer; and
a conductive material filling the contact hole, wherein TaN of the first TaN layer has a grain size smaller than a grain size of TaN of the second TaN layer.

2. The metal interconnection according to claim 1, wherein the first and second TaN layers are alternately formed at least once.

3. The metal interconnection according to claim 1, further comprising;
a third Ta layer formed on the second TaN layer; and
a fourth Ta layer formed on the third Ta layer.

4. The metal interconnection according to claim 3, wherein the third and fourth TaN layers are alternately formed at least once.

5. The metal interconnection according to claim 3, wherein TaN of the third TaN layer has a grain size smaller than a grain size of TaN of the fourth TaN layer.

6. The metal interconnection according to claim 1, wherein the contact hole comprises a via hole and a trench.

7. A method of fabricating a metal interconnection of a semiconductor device, the comprising:
forming a first layer comprising boron (B) on a substrate;
converting the first layer into a first Ta layer by reacting the first layer with TaF;
forming a second layer comprising silicon (Si) on the first Ta layer;
converting the second layer into a second Ta layer by reacting the second layer with TaF; and
converting the first and second Ta layers into TaN layers by reacting the first and second Ta layers with NH₃.

8. The method according to claim 7, further comprising repeating forming the first layer, converting the first layer forming the second layer, and converting the second layer before converting the first and second Ta layers into TaN layers.

9. The method according to claim 7, further comprising:
forming a third layer comprising boron (B) on the TaN layers;
converting the third layer into a third Ta layer by reacting the third layer with TaF;
forming a fourth layer comprising silicon (Si) on the third Ta layer; and
converting the fourth layer into a fourth Ta layer by reacting the fourth layer with TaF.

10. The method according to claim 9, wherein the first to fourth layers are formed by performing atom layer deposition (ALD).

11. The method according to claim 9, wherein the first and third layers are formed using B₂H₆ gas.

12. The method according to claim 9, wherein the second and fourth layers are formed using SiH₄ gas.

13. The method according to claim 9, further comprising repeating at least one of a first and a second process, wherein:
the first process comprises forming the first layer, converting the first layer, forming the second layer, and converting the second layer; and
the second process comprises forming the third layer, converting the third layer, forming the fourth layer, and converting the fourth layer.
